(19) United States
(12) Patent Application Publication
(10) Pub. No.: US 2026/0158550 A1
(43) Pub. Date: Jun. 11, 2026

(54) METHOD FOR MANUFACTURING CERAMIC ELECTRONIC COMPONENT

(71) Applicant: Murata Manufacturing Co., Ltd., Nagaokakyo-shi (JP)

(72) Inventors: Shu HAMADA, Nagaokakyo-shi (JP); Jun KOJIMA, Nagaokakyo-shi (JP)

(21) Appl. No.: 19/179,894

(22) Filed: Apr. 15, 2025

Related U.S. Application Data
(63) Continuation of application No. PCT/JP2023/039184, filed on Oct. 31, 2023.

(30) Foreign Application Priority Data
Nov. 9, 2022 (JP) 2022-179682

(51) Int. Cl. B22F 7/00; B22F 10/43; B22F 10/64; B28B 1/00; B33Y 10/00; B33Y 40/20; B33Y 70/10; B33Y 80/00; H01G 4/30

(52) U.S. Cl. CPC B22F 7/008; B22F 10/43; B22F 10/64; B28B 1/001; B33Y 10/00; B33Y 40/20; B33Y 70/10; B33Y 80/00; H01G 4/30; B22F 2301/10; B22F 2301/255; B22F 2302/253

(57) ABSTRACT

A method for manufacturing a ceramic electronic component that includes: forming a modeled object by applying a ceramic material, a metal material, and a disappearing material by 3D printing, the modeled object including an electronic component main body containing the ceramic material and the metal material, a support body that contains the ceramic material and that is disposed around at least a portion of a periphery of the electronic component main body, and a disappearing body that contains the disappearing material and that is disposed between the electronic component main body and the support body; firing the modeled object at a temperature higher than or equal to a temperature at which the disappearing body disappears; and isolating the support body from the modeled object after firing so as to obtain the ceramic electronic component.

### CROSS REFERENCE TO RELATED APPLICATIONS

The present application is a continuation of International application No. PCT/JP2023/039184, filed Oct. 31, 2023, which claims priority to Japanese Patent Application No. 2022-179682, filed Nov. 9, 2022, the entire contents of each of which are incorporated herein by reference.

### TECHNICAL FIELD

The present disclosure relates to a method for manufacturing a ceramic electronic component.

### BACKGROUND ART

Patent Document 1 discloses a method for manufacturing a multilayer electronic component including stacking a plurality of ceramic green sheets on which at least an insulator, an inner electrode conductor, an outer electrode conductor, and a disappearing material are patterned so that a portion serving as a corner portion of the multilayer electronic component has a substantially spherical roundness shape after stacking in a way that the disappearing material is patterned outside the substantially spherical roundness portion, continuously from the substantially spherical roundness portion, and at a position corresponding to a cutting allowance to divide a multilayer body of the ceramic green sheets into multilayer electronic components; and subjecting the multilayer body of the ceramic green sheets to specific treatment to make a region composed of the disappearing material disappear so as to simultaneously perform division into individual multilayer electronic components.

Patent Document 2 discloses a method for manufacturing a ceramic modeled object for an electronic component, the method including forming a three-dimensional shape by subjecting a multilayer body in which a plurality of sheet-like members containing at least an insulator material and a disappearing material are stacked to disappearing treatment so as to obtain the ceramic modeled object for an electronic component from the multilayer body.

Patent Document 3 discloses a method for manufacturing a ceramic product including a modeled object formation step of forming a three-dimensional modeled object including a ceramic body formed by using a first ink containing a ceramic material and a glaze film which is formed by using a second ink containing glaze and which covers at least a portion of the ceramic body by 3D printing to eject and deposit the first ink and the second ink by an ink jet system and a firing step of firing the three-dimensional modeled object formed in the modeled object formation step.
Patent Document 1: Japanese Unexamined Patent Application Publication No. 2005-311225
Patent Document 2: Japanese Unexamined Patent Application Publication No. 2006-41204
Patent Document 3: Japanese Unexamined Patent Application Publication No. 2019-142069

### SUMMARY OF THE DISCLOSURE

When the method for stacking ceramic green sheets is used in production of a ceramic electronic component as in the invention described in Patent Document 1 or Patent Document 2, the flexibility in the shape of the obtained ceramic electronic component is limited. On the other hand, it is conjectured that the flexibility in the shape of the obtained ceramic electronic component is increased by using the method in which the ceramic material is applied by 3D printing as in the invention described in Patent Document 3.

However, the present inventors produced a ceramic electronic component by using the method in which the ceramic material is applied by 3D printing as in the invention described in Patent Document 3 and found that it was difficult to obtain a ceramic electronic component having a predetermined shape due to deformation during firing in the production process when, in particular, a ceramic electronic component having a complex shape was produced.

The present disclosure was realized to address the above-described problem and is intended to provide a method for manufacturing a ceramic electronic component capable of suppressing deformation during firing regardless of a complex shape.

A method for manufacturing a ceramic electronic component according to the present disclosure includes: forming a modeled object by applying a ceramic material, a metal material, and a disappearing material by 3D printing with a material jetting system, the modeled object including an electronic component main body containing the ceramic material and the metal material, a support body that contains the ceramic material and that is disposed around at least a portion of a periphery of the electronic component main body, and a disappearing body that contains the disappearing material and that is disposed between the electronic component main body and the support body; firing the modeled object at a temperature higher than or equal to a temperature at which the disappearing body disappears; and isolating the support body from the modeled object after firing so as to obtain the ceramic electronic component.

According to the present disclosure, a method for manufacturing a ceramic electronic component capable of suppressing deformation during firing regardless of a complex shape can be provided.

### BRIEF DESCRIPTION OF THE DRAWINGS

FIG. 1 is a schematic perspective view illustrating a modeled object formed in a step of forming a modeled object in a method for manufacturing a ceramic electronic component according to a first embodiment of the present disclosure.

FIG. 2 is a schematic sectional view illustrating an example of a section taken along line a1-a2 of the modeled object in FIG. 1.

FIG. 3 is a schematic perspective view illustrating an electronic component main body obtained in a step of obtaining an electronic component main body in the method for manufacturing a ceramic electronic component according to the first embodiment of the present disclosure.

FIG. 4 is a schematic perspective view illustrating a modeled object formed on a printing foundation in a step of forming a modeled object in a modified example of the method for manufacturing a ceramic electronic component according to the first embodiment of the present disclosure.

FIG. 5 is a schematic perspective view illustrating a modeled object formed in a step of forming a modeled object in a method for manufacturing a ceramic electronic component according to a second embodiment of the present disclosure.

FIG. 6 is a schematic sectional view illustrating an example of a section taken along line b1-b2 of the modeled object in FIG. 5.

FIG. 7 is a schematic perspective view illustrating an electronic component main body with a connection body formed in the middle of a step of obtaining the electronic component main body in the method for manufacturing a ceramic electronic component according to the second embodiment of the present disclosure.

### DESCRIPTION OF THE PREFERRED EMBODIMENTS

A method for manufacturing a ceramic electronic component according to the present disclosure will be described below. In this regard, the present disclosure is not limited to the configuration described below and can be appropriately modified within the bounds of not departing from the scope of the present disclosure. In addition, the present disclosure also includes combinations of a plurality of individual desirable configurations described below.

It is needless to say that each of the embodiments described below is an exemplification and that configurations described in different embodiments can be partly replaced or combined with each other. Regarding the second and subsequent embodiments, descriptions of matters common to the first embodiment will be omitted, and different points will be mainly described below. In particular, regarding the same operations and advantages due to the same configuration, explanations will not be provided on an embodiment basis.

In the following explanations, when the embodiments are not particularly distinguished from each other, each embodiment is referred to simply as “the method for manufacturing a ceramic electronic component according to the present disclosure”.

The following drawings are schematic drawings, and dimensions, scales of the aspect ratio, and the like thereof may be different from that of actual products.

The method for manufacturing a ceramic electronic component according to the present disclosure includes forming a modeled object by applying a ceramic material, a metal material, and a disappearing material by 3D printing with a material jetting system, the modeled object including an electronic component main body containing the ceramic material and the metal material, a support body that contains the ceramic material and that is disposed on at least a portion of the periphery of the electronic component main body, and a disappearing body that contains the disappearing material and that is disposed between the electronic component main body and the support body, firing the modeled object at a temperature higher than or equal to a temperature at which the disappearing body disappears, and obtaining the electronic component main body in a state in which the support body is isolated from the modeled object after firing.

### First Embodiment

An example of the method for manufacturing a ceramic electronic component according to a first embodiment of the present disclosure will be described below.

### <Step of Forming Modeled Object>

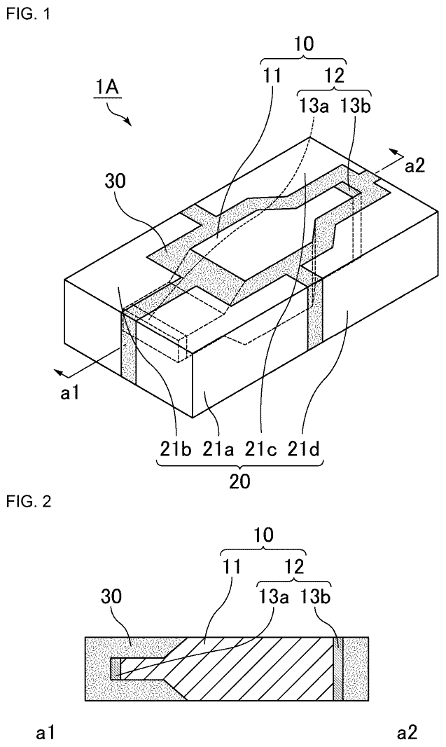

FIG. 1 is a schematic perspective view illustrating a modeled object formed in the method for manufacturing a ceramic electronic component according to the first embodiment of the present disclosure. FIG. 2 is a schematic sectional view illustrating an example of a section taken along line a1-a2 of the modeled object in FIG. 1.

A modeled object 1A illustrated in FIG. 1 and FIG. 2 is formed by applying a ceramic material, a metal material, and a disappearing material by 3D printing with a material jetting system.

The modeled object 1A includes an electronic component main body 10, a support body 20, and a disappearing body 30.

The electronic component main body 10 contains the ceramic material and the metal material.

The electronic component main body 10 includes a ceramic portion 11 containing the ceramic material and an electrode portion 12 that contains the metal material and that is in contact with the ceramic portion 11.

The electrode portion 12 may be composed of a single electrode member or may be composed of a plurality of electrode members.

In the example illustrated in FIG. 1 and FIG. 2, the electrode portion 12 is composed of two electrode members of a first electrode member 13a in contact with one end of the ceramic portion 11 and a second electrode member 13b in contact with the other end of the ceramic portion 11.

There is no particular limitation regarding the position of the electrode portion 12 relative to the ceramic portion 11. For example, the positions of the first electrode member 13a and the second electrode member 13b relative to the ceramic portion 11 are not limited to the positions illustrated in FIG. 1 and FIG. 2.

The support body 20 contains the ceramic material.

The ceramic material contained in the support body 20 is preferably the same as the ceramic material contained in the electronic component main body 10 (ceramic portion 11) but may differ from the ceramic material contained in the electronic component main body 10 (ceramic portion 11).

The support body 20 is disposed on at least a portion of the periphery of the electronic component main body 10. The support body 20 may be disposed around a portion of the periphery of the electronic component main body 10 as illustrated in FIG. 1, or may be disposed around the entire periphery of the electronic component main body 10. That is, the support body 20 may cover a portion of the electronic component main body 10 as illustrated in FIG. 1 or may cover the entire electronic component main body 10.

The disappearing body 30 includes the disappearing material.

The disappearing body 30 is disposed between the electronic component main body 10 and the support body 20. More specifically, the disappearing body 30 is disposed so as to fill between the electronic component main body 10 and the support body 20. Consequently, the disappearing body 30 is in contact with both the electronic component main body 10 and the support body 20.

Examples of the ceramic material include alumina, aluminum nitride, and low-temperature-co-fired ceramic (LTCC) materials. Of these, it is preferable that the ceramic material be a low-temperature-co-fired ceramic material.

In the present specification, of the ceramic materials, the low-temperature-co-fired ceramic material means a ceramic material sinterable at a firing temperature of 1,000° C. or lower.

Examples of the low-temperature-co-fired ceramic material include glass-composite-based low-temperature-co-fired ceramic materials containing a ceramic material, such as quartz, alumina, or forsterite, and borosilicate glass, crystallized-glass-based low-temperature-co-fired ceramic materials containing ZnO—MgO—Al₂O₃—SiO₂-based crystallized glass, and non-glass-based low-temperature-co-fired ceramic materials containing BaO—Al₂O₃—SiO₂-based ceramic materials, Al₂O₃—CaO—SiO₂—MgO—B₂O₃-based ceramic materials, or the like. Of these, a low-temperature-co-fired ceramic material in which a main material is alumina and SiO₂ is added is preferable.

The metal material is preferably a material that can be co-fired with the ceramic material and more preferably a material that can be co-fired with the low-temperature-co-fired ceramic material. That is, the melting point of the metal material is preferably higher than the sintering temperature of the ceramic material and more preferably higher than the sintering temperature of the low-temperature-co-fired ceramic material. Examples of the metal material include copper, silver, and alloys containing at least one of these metals.

The disappearing material is preferably a material that disappears at a temperature lower than or equal to the sintering temperature of the ceramic material and more preferably a material that disappears at a temperature lower than or equal to the sintering temperature of the low-temperature-co-fired ceramic material. Examples of the disappearing material include organic resins and carbon black.

Examples of the method for forming a modeled object 1A by using 3D printing with a material jetting system include a method described below. Initially, a first ink containing the ceramic material, a second ink containing the metal material, and a third ink containing the disappearing material are prepared. After each ink is applied in a predetermined pattern by being ejected from an ink jet head, the obtained coating film is dried with hot air or the like. Thereafter, application of each ink and drying of the coating film are repeated so as to stack, in a predetermined pattern, a ceramic layer containing the ceramic material, a metal layer containing the metal material, and a disappearing layer containing the disappearing material. Consequently, the modeled object 1A including the electronic component main body 10 in which the ceramic layer and the metal layer are stacked, the support body 20 in which the ceramic layer is stacked, and the disappearing body 30 in which the disappearing layer is stacked is formed.

When, for example, the method in which ceramic green sheets are stacked, as in the invention described in Patent Document 1 or Patent Document 2, is used in formation of the modeled object 1A having the above-described complex structure, many masks (plates) are necessary and, as a result, the production efficiency deteriorates.

On the other hand, in the present embodiment, since the 3D printing with the material jetting system is used in formation of the modeled object 1A, a mask (plate) is unnecessary. Consequently, according to the present embodiment, even when a modeled object having a complex structure, and therefore, the electronic component main body 10 having a complex shape, is formed, the production efficiency is suppressed from deteriorating.

The first ink may further contain a resin, a solvent, and the like in addition to the ceramic material.

Examples of the resin include ethyl cellulose, acryl, and polyvinyl butyral. When such a resin is contained in the first ink, the resin is cured during the above-described drying of the coating film and functions as a binder with respect to the ceramic material. Such a resin is removed during, for example, firing of the modeled object described later.

Examples of the solvent include organic solvents, such as methanol and ethanol, inorganic solvents, such as water, and mixtures thereof. Such a solvent is removed during, for example, firing of the coating film described above.

Likewise, the second ink and the third ink may further contain the above-described resins, solvents, and the like.

When the modeled object 1A is formed, instead of the above-described method in which the coating film is dried, for example, each ink may be applied in a predetermined pattern by being ejected from an ink jet head, and the obtained coating film may be irradiated with radiation (preferably ultraviolet rays) so as to cure the coating film. In such an instance, it is sufficient that each ink is a radiation-curable ink (preferably ultraviolet-curable ink) that is cured by radiation (preferably ultraviolet rays), and each ink may contain preferably a radiation-polymerizable compound (preferably ultraviolet-polymerizable compound) and may further contain a polymerization initiator, a solvent, and the like, as the situation demands.

### <Step of Firing Modeled Object>

The modeled object 1A is fired at a temperature higher than or equal to a temperature at which the disappearing body 30 disappears. Consequently, the disappearing body 30 is made to disappear from the modeled object 1A, and in addition, the ceramic material contained in the modeled object 1A, in particular, the ceramic material contained in the electronic component main body 10, is sintered.

In this regard, for example, when the modeled object 1A is composed of only the electronic component main body 10, firing is performed in the state in which the entire electronic component main body 10 is exposed. In such an instance, since the ceramic material contained in the electronic component main body 10 (ceramic portion 11) moves so as to decrease the surface area of the electronic component main body 10, in particular, when the electronic component main body 10 has a complex shape, large surface tension tends to occur during firing due to a large specific surface area of the electronic component main body 10. As a result, the electronic component main body 10 tends to be deformed during firing.

On the other hand, in the present embodiment, when the electronic component main body 10 is fired, since the support body 20 is disposed on at least a portion of the periphery of the electronic component main body 10, even when the electronic component main body 10 has a complex shape, the electronic component main body 10 is suppressed from being deformed during firing. Further, since the modeled object 1A being fired in the present step enables the disappearing body 30 to disappear from the modeled object 1A and enables the ceramic material contained in the modeled object 1A, in particular, the ceramic material contained in the electronic component main body 10 to be sintered, the production efficiency is improved.

### <Step of Obtaining Electronic Component Main Body>

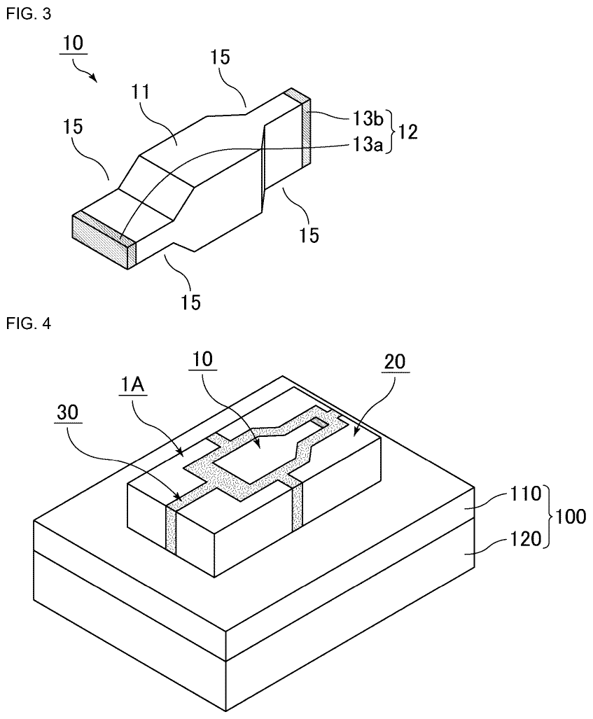

FIG. 3 is a schematic perspective view illustrating an electronic component main body obtained in a step of obtaining an electronic component main body in the method for manufacturing a ceramic electronic component according to the first embodiment of the present disclosure.

As illustrated in FIG. 3, the electronic component main body 10 in a state in which the support body 20 is isolated from the modeled object 1A after firing is obtained as the ceramic electronic component.

In the process of obtaining the electronic component main body 10 in a state in which the support body 20 is isolated from the modeled object 1A, the support body 20 may be artificially removed from the modeled object 1A, or the support body 20 may naturally come off the modeled object 1A in accordance with disappearance of the disappearing body 30.

According to the above-described step, the ceramic electronic component can be produced without deformation during firing even when having a complex shape.

There is no particular limitation regarding the ceramic electronic component produced by the above-described step, and examples include multilayer ceramic capacitors.

The example in which one ceramic electronic component is obtained from one modeled object 1A is described above, but a plurality of ceramic electronic components may be obtained from one modeled object 1A. That is, in the step of forming the modeled object 1A, a plurality of electronic component main bodies 10 may be formed in the modeled object 1A.

As illustrated in FIG. 3, the electronic component main body 10 may have an irregular shape in which a recessed portion 15 is formed. That is, in the step of forming the modeled object 1A, the electronic component main body 10 may be formed so as to have an irregular shape in which a recessed portion 15 is formed.

In the present specification, an irregular shape means a shape in which a recessed portion is partly formed in a supposed base shape (for example, a simple shape, such as a rectangular parallelepiped shape). For example, the electronic component main body 10 illustrated in FIG. 3 has an irregular shape in which four recessed portions 15 are formed in a rectangular parallelepiped shape that is a supposed base shape.

When the electronic component main body 10 has an irregular shape, the number of the recessed portions 15 may be one or may be more than one as illustrated in FIG. 3.

When the electronic component main body 10 has an irregular shape, the shape is not limited to the shape illustrated in FIG. 3.

In the present embodiment, even when the electronic component main body 10 has a complex shape such as an irregular shape, the electronic component main body 10 is suppressed from being deformed during firing since the support body 20 is disposed on at least a portion of the periphery of the electronic component main body 10 in the modeled object 1A.

In this regard, when a plurality of electronic component main bodies 10 are formed in the step of forming the modeled object 1A, of the electronic component main bodies 10, all electronic component main bodies 10 may have an irregular shape, or a portion of electronic component main bodies 10 may have an irregular shape.

In this regard, the electronic component main body 10 is not limited to having a complex shape such as an irregular shape and may have a simple shape, such as a rectangular parallelepiped shape.

As illustrated in FIG. 1 and FIG. 3, it is preferable that the support body 20 cover the recessed portion 15 of the electronic component main body 10. That is, in the step of forming the modeled object 1A, it is preferable that the support body 20 be formed so as to cover the recessed portion 15 of the electronic component main body 10.

Even when the electronic component main body 10 has an irregular shape in which the recessed portion 15 is formed, the support body 20 covering the recessed portion 15 of the electronic component main body 10 sufficiently suppresses electronic component main body 10 from being deformed during firing.

When a plurality of recessed portions 15 are formed in the electronic component main body 10 as illustrated in FIG. 3, it is preferable that the support body 20 cover all recessed portions 15 of the plurality of recessed portions 15.

In this regard, when a plurality of recessed portions 15 are formed in the electronic component main body 10 as illustrated in FIG. 3, the support body 20 may cover a portion of recessed portions 15 of the plurality of recessed portions 15.

The support body 20 may cover a portion other than the recessed portion 15 of the electronic component main body 10 in addition to covering the recessed portion 15 or is not limited to covering a portion other than the recessed portion 15.

In this regard, when a plurality of electronic component main bodies 10 are formed in the step of forming the modeled object 1A, it is preferable that the support body 20 cover the recessed portion 15, as described above, with respect to all electronic component main bodies 10 of the plurality of electronic component main bodies 10.

Alternatively, when a plurality of electronic component main bodies 10 are formed in the step of forming the modeled object 1A, the support body 20 may cover the recessed portion 15, as described above, with respect to a portion of electronic component main bodies 10 of the plurality of electronic component main bodies 10.

As illustrated in FIG. 1 and FIG. 3, it is preferable that the volume of the support body 20 be larger than the volume of the electronic component main body 10. That is, it is preferable that the support body 20 be formed so as to have larger volume than the electronic component main body 10 in the step of forming the modeled object 1A.

The volume of the support body 20 being larger than the volume of the electronic component main body 10 sufficiently suppresses electronic component main body 10 from being deformed during firing since the support body 20 has sufficiently large effect on the electronic component main body 10.

In this regard, when a plurality of electronic component main bodies 10 are formed in the step of forming the modeled object 1A, it is preferable that the volume of the support body 20 be larger than the total volume of the electronic component main bodies 10.

As illustrated in FIG. 1, it is preferable that the support body 20 be composed of a plurality of support members. That is, it is preferable that the support body 20 be formed so as to be composed of a plurality of support members in the step of forming the modeled object 1A.

In the example illustrated in FIG. 1, the support body 20 is composed of four support members of a first support member 21a, a second support member 21b, a third support member 21c, and a fourth support member 21d.

When the support body 20 is composed of a plurality of support members, the electronic component main body 10 in the state in which the support body 20 is isolated from the modeled object 1A is readily obtained compared to the instance in which the support body 20 is composed of one support member since, for example, it becomes easy to remove the electronic component main body 10 from the modeled object 1A in the step of obtaining the electronic component main body 10 (the electronic component main body 10 is readily removed).

### Modified Example of First Embodiment

In the method for manufacturing a ceramic electronic component according to the first embodiment of the present disclosure, the modeled object may be formed on a printing foundation in the step of forming the modeled object, the modeled object may be fired on the printing foundation in the step of firing the modeled object, and the modeled object may be isolated from the printing foundation during firing in the step of firing the modeled object. Such examples will be described below as modified examples of the method for manufacturing a ceramic electronic component according to the first embodiment of the present disclosure.

FIG. 4 is a schematic perspective view illustrating a modeled object formed on the printing foundation in a step of forming a modeled object in a modified example of the method for manufacturing a ceramic electronic component according to the first embodiment of the present disclosure.

As illustrated in FIG. 4, the modeled object 1A may be formed on a printing foundation 100 in the step of forming the modeled object 1A. Further, the modeled object 1A may be fired on the printing foundation 100 in the step of firing the modeled object 1A. Further, the modeled object 1A may be isolated from the printing foundation 100 during firing in the step of firing the modeled object 1A.

In the above-described method, since the modeled object 1A is formed on the printing foundation 100, and thereafter the modeled object 1A is fired as it is on the printing foundation 100, when firing is performed, it is not necessary to move the modeled object 1A from the printing foundation 100 to a foundation for firing. Further, in the above-described method, since the modeled object 1A is isolated from the printing foundation 100 during firing, a step of isolating the modeled object 1A after firing from the printing foundation 100 can be skipped. Therefore, in the above-described method, even when the modeled object 1A is formed on the printing foundation 100, the production efficiency is suppressed from deteriorating.

In addition, in the above-described method, since the modeled object 1A is isolated from the printing foundation 100 during firing, the modeled object 1A can freely shrink during firing without being influenced by the printing foundation 100. Therefore, when the modeled object 1A shrinks during firing, cracking or deformation due to an influence of the printing foundation 100 is suppressed from occurring.

As illustrated in FIG. 4, it is preferable that the printing foundation 100 include, on the surface thereof, a disappearing portion 110 that disappears during firing in the step of firing the modeled object 1A. That is, in the step of firing the modeled object 1A, it is preferable that the disappearing portion 110 included on the surface of the printing foundation 100 disappear during firing.

The modeled object 1A is readily isolated from the printing foundation 100 during firing by the printing foundation 100 including, on the surface, a disappearing portion 110 that disappears during firing.

The temperature at which the disappearing portion 110 disappears is preferably lower than the temperature at which the disappearing body 30 disappears. That is, in the step of firing the modeled object 1A, it is preferable that the disappearing portion 110 disappear before the disappearing body 30 disappears.

When the temperature at which the disappearing portion 110 disappears is lower than the temperature at which the disappearing body 30 disappears, the disappearing portion 110 readily disappears before the modeled object 1A shrinks during firing, and as a result, the modeled object 1A is readily isolated from the printing foundation 100. Consequently, the modeled object 1A readily freely shrinks during firing without being influenced by the printing foundation 100. Therefore, when the modeled object 1A shrinks during firing, cracking or deformation due to an influence of the printing foundation 100 is sufficiently suppressed from occurring.

It is preferable that the disappearing portion 110 include a plurality of resin particles in which at least a portion of the surface is covered with polyvinyl alcohol. In such an instance, the disappearing portion 110 may include a plurality of resin particles in which the entire surface is covered with polyvinyl alcohol, may include a plurality of resin particles in which at least a portion of the surface is covered with polyvinyl alcohol, or may include both the resin particle in which the entire surface is covered with polyvinyl alcohol and the resin particle in which at least a portion of the surface is covered with polyvinyl alcohol.

When the disappearing portion 110 includes a plurality of resin particles in which at least a portion of the surface is covered with polyvinyl alcohol, the disappearing portion 110 readily disappears during firing. Further, the disappearing portion 110 readily disappears before the modeled object 1A shrinks during firing, and as a result, the modeled object 1A is readily isolated from the printing foundation 100. Consequently, the modeled object 1A readily freely shrinks during firing without being influenced by the printing foundation 100. Therefore, when the modeled object 1A shrinks during firing, cracking or deformation due to an influence of the printing foundation 100 is sufficiently suppressed from occurring.

The disappearing portion 110 may further include a resin particle in which the surface is not covered with polyvinyl alcohol in addition to the plurality of resin particles in which at least a portion of the surface is covered with polyvinyl alcohol.

The resin particle may include an acrylic resin, a cellulose resin, a polyvinyl butyral resin, or the like. Of these, the resin particle preferably includes an acrylic resin. When the resin particle includes an acrylic resin, the acrylic resin is preferably a methyl methacrylate·ethylene glycol dimethacrylate copolymer ({CH₂C(CH₃)COOCH₃}ₘ·{CH₂C(CH₃)COOCH₂CH₂OOC(CH₃)CCH₂}ₙ).

There is no particular limitation regarding the shape of the resin particle, and examples include a spherical shape, a spheroidal shape (a shape obtained by rotating an ellipsoid around the major axis or the minor axis serving as an axis of rotation), a rectangular parallelepiped shape, a triangular pyramid shape, a cylindrical shape, a conical shape, and other irregular shapes.

When the resin particle has a spherical shape, the average particle diameter of the resin particle is preferably 1.8 μm or less.

The polyvinyl alcohol to cover the surface of the resin particle may contain impurities, such as methanol and methyl acetate.

In the disappearing portion 110, it is preferable that a plurality of resin particles in which at least a portion of the surface is covered with polyvinyl alcohol be connected to each other with the polyvinyl alcohol interposed therebetween.

The thickness of the disappearing portion 110 is preferably 5 μm or more.

As illustrated in FIG. 4, it is preferable that the printing foundation 100 further include a support portion 120 that is a porous structure and that is disposed in contact with the disappearing portion 110.

When the printing foundation 100 further includes a support portion 120 that is a porous structure and that is disposed in contact with disappearing portion 110, the modeled object 1A can be fired in the state in which an external force other than gravity is not readily applied to the modeled object 1A coupled with the state in which the surface of the printing foundation 100 tends to become flat. As a result, when the modeled object 1A shrinks during firing, cracking or deformation due to an influence of the printing foundation 100 is sufficiently suppressed from occurring.

The support portion 120 may contain Al₂O₃. In such an instance, the support portion 120 may include, for example, a material containing aluminum oxide (Al₂O₃) as a primary component.

The support portion 120 may contain a compound of Al₂O₃ and SiO₂. In such an instance, the support portion 120 may include, for example, a material containing mullite (3Al₂O₃·2SiO₂) as a primary component.

The support portion 120 may contain a compound of Al₂O₃, SiO₂, and MgO. In such an instance, the support portion 120 may include, for example, a material containing cordierite (2MgO·2Al₂O₃·5SiO₂) as a primary component.

The support portion 120 may further contain a secondary component, impurities, and the like in such an amount that does not change the characteristics in addition to the above-described primary component.

### Second Embodiment

In a method for manufacturing a ceramic electronic component according to a second embodiment of the present disclosure, a modeled object contains a ceramic material and further includes a connection body to connect an electronic component main body and a support body. The method for manufacturing a ceramic electronic component according to the second embodiment of the present disclosure is similar to the method for manufacturing a ceramic electronic component according to the first embodiment of the present disclosure except for the above-described point.

### <Step of Forming Modeled Object>

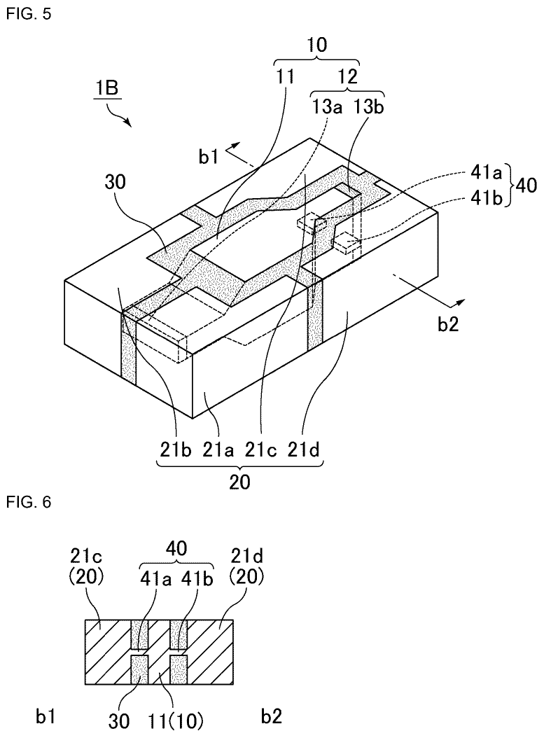

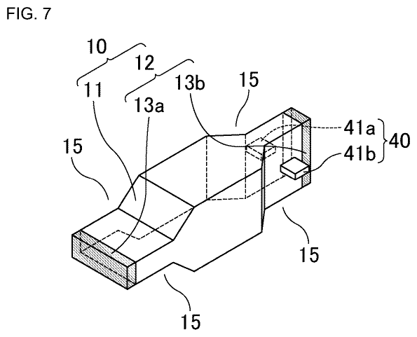

FIG. 5 is a schematic perspective view illustrating a modeled object formed in a step of forming a modeled object in a method for manufacturing a ceramic electronic component according to the second embodiment of the present disclosure. FIG. 6 is a schematic sectional view illustrating an example of a section taken along line b1-b2 of the modeled object in FIG. 5.

A modeled object 1B illustrated in FIG. 5 and FIG. 6 is formed by applying a ceramic material, a metal material, and a disappearing material by 3D printing with a material jetting system.

The modeled object 1B includes an electronic component main body 10, a support body 20, a disappearing body 30, and a connection body 40. That is, the modeled object 1B has a configuration in which the connection body 40 is disposed in the modeled object 1A (refer to FIG. 1 and FIG. 2).

The connection body 40 contains a ceramic material.

The ceramic material contained in the connection body 40 is preferably the same as the ceramic material contained in the electronic component main body 10 (ceramic portion 11) but may differ from the ceramic material contained in the electronic component main body 10 (ceramic portion 11).

The ceramic material contained in the connection body 40 is preferably the same as the ceramic material contained in the support body 20 but may differ from the ceramic material contained in the support body 20.

That is, the ceramic material contained in the electronic component main body 10 (ceramic portion 11), the ceramic material contained in the support body 20, and the ceramic material contained in the connection body 40 are preferably the same as each other but may differ from each other, or a portion of these may differ from the other.

The connection body 40 connects the electronic component main body 10 and the support body 20. That is, the connection body 40 is in contact with both the electronic component main body 10 and the support body 20.

It is preferable that the connection body 40 connect the ceramic portion 11 and the support body 20. That is, it is preferable that the connection body 40 be in contact with both the ceramic portion 11 and the support body 20.

In this regard, the connection body 40 may connect an electrode portion 12 and the support body 20. That is, the connection body 40 may be in contact with both the electrode portion 12 and the support body 20.

The connection body 40 may be composed of a single connection member or may be composed of a plurality of connection members.

In the example illustrated in FIG. 5 and FIG. 6, the connection body 40 is composed of two connection members of a first connection member 41a to connect the ceramic portion 11 and the third support member 21c and a second connection member 41b to connect the ceramic portion 11 and the fourth support member 21d.

There is no particular limitation regarding the position of the connection body 40 relative to the electronic component main body 10. For example, the positions of the first connection member 41a and the second connection member 41b relative to the ceramic portion 11 are not limited to the positions illustrated in FIG. 5 and FIG. 6.

There is no particular limitation regarding the position of the connection body 40 relative to the support body 20. For example, the position of the first connection member 41a relative to the third support member 21c and the position of the second connection member 41b relative to the fourth support member 21d are not limited to the positions illustrated in FIG. 5 and FIG. 6.

### <Step of Firing Modeled Object>

The modeled object 1B is fired at a temperature higher than or equal to a temperature at which the disappearing body 30 disappears. Consequently, the disappearing body 30 is made to disappear from the modeled object 1B, and in addition, the ceramic material contained in the modeled object 1B, in particular, the ceramic material contained in the electronic component main body 10, is sintered.

In the present embodiment, since the modeled object 1B includes the connection body 40 to connect the electronic component main body 10 and the support body 20, the electronic component main body 10 is fixed to the support body 20 disposed on at least a portion of the periphery of the electronic component main body 10 with the connection body 40 interposed therebetween. Consequently, the electronic component main body 10 is sufficiently suppressed from being deformed during firing.

### <Step of Obtaining Electronic Component Main Body>

FIG. 7 is a schematic perspective view illustrating an electronic component main body with a connection body formed in the middle of a step of obtaining the electronic component main body in the method for manufacturing a ceramic electronic component according to the second embodiment of the present disclosure.

As illustrated in FIG. 7, the electronic component main body 10 with the connection body 40 in a state in which the support body 20 is isolated from the modeled object 1B after firing is obtained.

Thereafter, the electronic component main body 10 illustrated in FIG. 3 is obtained as a ceramic electronic component by removing the connection body 40 from the electronic component main body 10 with the connection body 40.

There is no particular limitation regarding the method for removing the connection body 40, and examples of the method include cutting and grinding (for example, blast treatment). The trace of removal of the connection body 40 by these methods is left on the electronic component main body 10 (herein, ceramic portion 11).

### Modified Example of Second Embodiment

In the method for manufacturing a ceramic electronic component according to the second embodiment of the present disclosure, the modeled object may be formed on a printing foundation in the step of forming the modeled object, the modeled object may be fired on the printing foundation in the step of firing the modeled object, and the modeled object may be isolated from the printing foundation during firing in the step of firing the modeled object. Modified examples of the method for manufacturing a ceramic electronic component according to the second embodiment of the present disclosure are such examples and are similar to the modified examples of the method for manufacturing a ceramic electronic component according to the first embodiment of the present disclosure with respect to the point that the printing foundation is used.

The following contents are disclosed in the present specification.

<1> A method for manufacturing a ceramic electronic component, the method including: forming a modeled object by applying a ceramic material, a metal material, and a disappearing material by 3D printing, the modeled object including an electronic component main body containing the ceramic material and the metal material, a support body that contains the ceramic material and that is disposed around at least a portion of a periphery of the electronic component main body, and a disappearing body that contains the disappearing material and that is disposed between the electronic component main body and the support body; firing the modeled object at a temperature higher than or equal to a temperature at which the disappearing body disappears; and isolating the support body from the modeled object after firing so as to obtain the ceramic electronic component.

<2> The method for manufacturing a ceramic electronic component according to <1>, wherein the electronic component main body has an irregular shape with a recessed portion.

<3> The method for manufacturing a ceramic electronic component according to <2>, wherein the support body covers the recessed portion of the electronic component main body.

<4> The method for manufacturing a ceramic electronic component according to any one of <1> to <3>, wherein a volume of the support body is larger than a volume of the electronic component main body.

<5> The method for manufacturing a ceramic electronic component according to any one of <1> to <4>, wherein the support body comprises a plurality of support members.

<6> The method for manufacturing a ceramic electronic component according to any one of <1> to <5>, wherein the modeled object contains the ceramic material and further includes a connection body that connects the electronic component main body and the support body.

<7> The method for manufacturing a ceramic electronic component according to any one of <1> to <6>, wherein the modeled object is formed on a printing foundation, the modeled object is fired on the printing foundation, and the modeled object is isolated from the printing foundation during the firing.

<8> The method for manufacturing a ceramic electronic component according to <7>, wherein the printing foundation includes, on a surface thereof, a disappearing portion that disappears during the firing of the modeled object.

<9> The method for manufacturing a ceramic electronic component according to <8>, wherein a temperature at which the disappearing portion disappears is lower than the temperature at which the disappearing body disappears.

<10> The method for manufacturing a ceramic electronic component according to <8> or <9>, wherein the disappearing portion includes a plurality of resin particles in which at least a portion of the surfaces thereof are covered with polyvinyl alcohol.

<11> The method for manufacturing a ceramic electronic component according to any one of <8> to <10>, wherein the printing foundation further includes a support portion that is a porous structure and that is disposed in contact with the disappearing portion.

### REFERENCE SIGNS LIST

1A, 1B modeled object
10 electronic component main body
11 ceramic portion
12 electrode portion
13a first electrode member
13b second electrode member
15 recessed portion
20 support body
21a first support member
21b second support member
21c third support member
21d fourth support member
30 disappearing body
40 connection body
41a first connection member
41b second connection member
100 printing foundation
110 disappearing portion
120 support portion

1. A method for manufacturing a ceramic electronic component, the method comprising:
forming a modeled object by applying a ceramic material, a metal material, and a disappearing material by 3D printing, the modeled object including an electronic component main body containing the ceramic material and the metal material, a support body that contains the ceramic material and that is disposed around at least a portion of a periphery of the electronic component main body, and a disappearing body that contains the disappearing material and that is disposed between the electronic component main body and the support body;
firing the modeled object at a temperature higher than or equal to a temperature at which the disappearing body disappears; and
isolating the support body from the modeled object after firing so as to obtain the ceramic electronic component.

2. The method for manufacturing the ceramic electronic component according to claim 1,
wherein the electronic component main body is formed so as to have an irregular shape with a recessed portion,
the recessed portion being formed so as to create a height difference between two planes constituting a surface of the electronic component main body, and
the support body is not part of the surface of the electronic component main body.

3. The method for manufacturing a ceramic electronic component according to claim 1, wherein the electronic component main body has an irregular shape with a recessed portion.

4. The method for manufacturing a ceramic electronic component according to claim 2, wherein the support body covers the recessed portion of the electronic component main body.

5. The method for manufacturing a ceramic electronic component according to claim 1, wherein a volume of the support body is larger than a volume of the electronic component main body.

6. The method for manufacturing a ceramic electronic component according to claim 1, wherein the support body comprises a plurality of support members.

7. The method for manufacturing a ceramic electronic component according to claim 1, wherein the modeled object contains the ceramic material and further includes a connection body that connects the electronic component main body and the support body.

8. The method for manufacturing a ceramic electronic component according to claim 1,
wherein the modeled object is formed on a printing foundation,
the modeled object is fired on the printing foundation, and
the modeled object is isolated from the printing foundation during the firing.

9. The method for manufacturing a ceramic electronic component according to claim 8, wherein the printing foundation includes, on a surface thereof, a disappearing portion that disappears during the firing of the modeled object.

10. The method for manufacturing a ceramic electronic component according to claim 9, wherein a temperature at which the disappearing portion disappears is lower than the temperature at which the disappearing body disappears.

11. The method for manufacturing a ceramic electronic component according to claim 9, wherein the disappearing portion includes a plurality of resin particles in which at least a portion of the surfaces thereof are covered with polyvinyl alcohol.

12. The method for manufacturing a ceramic electronic component according to claim 9, wherein the printing foundation further includes a support portion that is a porous structure and that is disposed in contact with the disappearing portion.

13. The method for manufacturing a ceramic electronic component according to claim 12, wherein the disappearing portion is adjacent to the modeled object.

14. The method for manufacturing a ceramic electronic component according to claim 1, wherein the ceramic material contained in the support body is the same as the ceramic material contained in the electronic component main body.

15. The method for manufacturing a ceramic electronic component according to claim 1, wherein the ceramic material contained in the support body is different from the ceramic material contained in the electronic component main body.

16. The method for manufacturing a ceramic electronic component according to claim 1, wherein the ceramic material is a low-temperature-co-fired ceramic material.
